(19) United States
(12) Patent Application Publication
(10) Pub. No.: US 2004/0125541 A1
(43) Pub. Date: Jul. 1, 2004

(54) Capacitor having oxygen diffusion barrier and method for fabricating the same

(76) Inventor: Hyun-Jin Chung, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/625,174

(22) Filed: Jul. 22, 2003

(30) Foreign Application Priority Data
Dec. 30, 2002 (KR) 2002-86263

(51) Int. Cl. H01G 4/228

(52) U.S. Cl. 361/306.3

(57) ABSTRACT

The present invention provides a capacitor having a dual oxygen diffusion barrier layer. The capacitor includes an electrode, a dual oxygen diffusion barrier layer containing an aluminum layer on the electrode, a dielectric layer on the oxygen diffusion barrier layer and a top electrode on the dielectric layer.

### FIELD OF THE INVENTION

The present invention relates to a semiconductor device; and, more particularly, to a capacitor having an alumina layer as an oxygen diffusion barrier in the semiconductor device and a method for fabricating the same.

### DESCRIPTION OF RELATED ART

As an integration degree of a semiconductor device such a DRAM is highly increased, dielectric materials having a high capacitance are employed. Specially, materials of a metal oxide family such Ta₂O₅, TiO₂, TaON, HfO₂, Al₂O₃ and ZrO₂ have been developed as a dielectric material of the capacitor.

A tantalum oxide (Ta₂O₅) layer, which has been applied as a dielectric layer of a capacitor in a cell of a highly integrated semiconductor device over 256M DRAM, has a capacitance (εᵣ) of about 25. The tantalum oxide layer has three or four times capacitance than that of a stacked dielectric layer of a silicon nitride (Si₃N₄, εᵣ=˜7)/silicon oxide (SiO₂, εᵣ=˜3.8) layer, which is generally employed as a dielectric layer of a capacitor.

FIG. 1A is a cross-sectional view showing a metal-oxide-silicon (MIS) capacitor of a cylinder type according to the prior art. A tantalum oxide layer is used as a dielectric layer of the capacitor.

As shown, an interlayer insulating layer 12 and an etching barrier layer 13 are formed on a semiconductor substrate 11 having a transistor and a bit line (not shown). A storage node contact 14 is connected to the semiconductor substrate 11 by passing through the etching barrier layer 13 and the interlayer insulating layer 12. Thereafter, a storage node oxide layer 15 is formed on the etching barrier layer 13 and then the storage oxide layer 15 is selectively etched to expose the storage node contact 14. When the storage oxide layer 15 is etched, a portion of the interlayer insulating layer 12 is undercut below the etching barrier layer 13, so that a top side and a portion of lateral side of the storage node contact 14 are exposed.

Subsequently, a bottom electrode 16 of a cylinder type, which is connected to the storage node contact 14, is formed to be fitted in the undercut of the interlayer insulating layer 12, and then hemi-spherical grains 17 are formed on a surface of the bottom electrode 16. A silicon nitride layer 18 is formed on a surface of the hemi-spherical grains 17. Thereafter, a tantalum oxide layer 19 and a top electrode 20 are sequentially formed on the silicon nitride layer 18.

FIG. 1B is a detailed cross-sectional view of “A” in FIG. 1A.

As shown, after forming the hemi-spherical grains 18 on the bottom electrode 16, the silicon nitride layer 18 is formed by a surface nitrification process. After the tantalum oxide layer 19 is formed on the silicon nitride layer 18, a thermal treatment process is carried out to crystallize the tantalum oxide layer 19 and to secure a desired capacitance. Thereafter, the top electrode 20 is formed on the tantalum oxide layer 19.

However, since the silicon nitride layer 18 cannot efficiently prevent an oxygen diffusion toward the bottom electrode 16 during a post thermal process of the tantalum oxide layer 19 according to the prior art, there is a problem that a low-k dielectric layer such a silicon oxide (SiO₂, εᵣ=3.9) layer is thickly formed on a surface of the bottom electrode.

Since the low-k dielectric layer degrades an electric characteristic of the capacitor, a stable operation of a semiconductor device cannot be expected. Namely, a capacitance of the capacitor is decreased and a leakage current is increased.

### SUMMARY OF THE INVENTION

It is, therefore, an object of the present invention to provide a capacitor having a dual oxygen diffusion barrier layer including an alumina layer in the semiconductor device and a method for fabricating the same.

In accordance with an aspect of the present invention, there is provided a capacitor including: an electrode; an oxygen diffusion barrier layer containing aluminum on the electrode; a dielectric layer on the oxygen diffusion barrier layer; and a top electrode on the dielectric layer.

In accordance with another aspect of the present invention, there is provided a method fabricating a capacitor, including the steps of: a) forming an bottom electrode; b) forming an oxygen diffusion barrier layer containing aluminum on the bottom electrode; c) forming a dielectric layer on the oxygen diffusion barrier layer; and d) forming a top electrode on the dielectric layer.

### BRIEF DESCRIPTION OF THE DRAWINGS

The above and other objects and features of the instant invention will become apparent from the following description of preferred embodiments taken in conjunction with the accompanying drawings, in which:

FIG. 1A is a cross-sectional view showing a metal-oxide-silicon (MIS) capacitor of a cylinder type according to the prior art;

FIG. 1B is a detailed cross-sectional view of “A” in FIG. 1A;

FIG. 2 is a cross-sectional view showing a capacitor structure in accordance with the present invention; and

FIGS. 3A to 3E are cross-sectional views showing a method for fabricating the capacitor illustrated in FIG. 2 in accordance with the present invention.

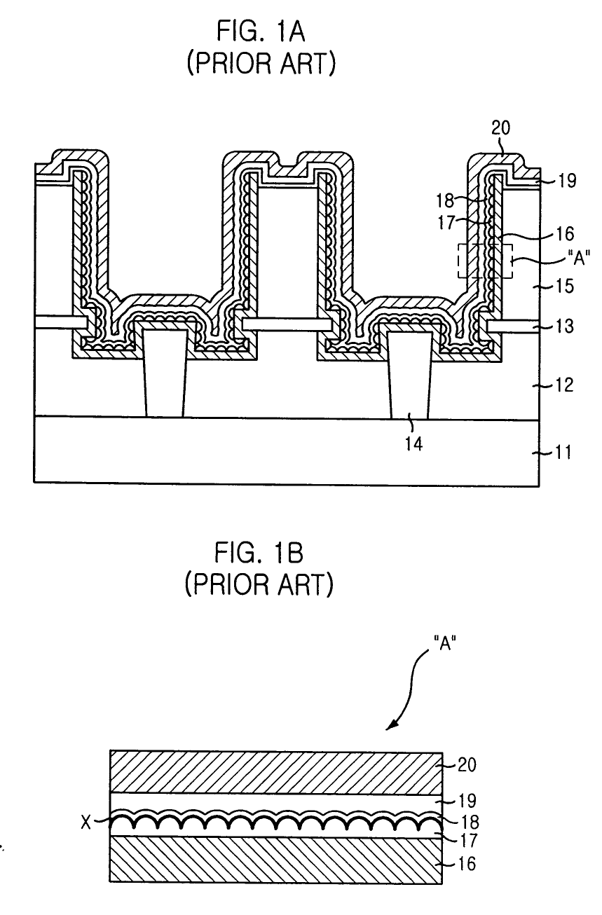

### DETAILED DESCRIPTION OF THE INVENTION

Hereinafter, a capacitor capable of suppressing an oxide layer formed between a bottom electrode and a dielectric layer and a method for fabricating the same according to the present invention will be described in detail referring to the accompanying drawings.

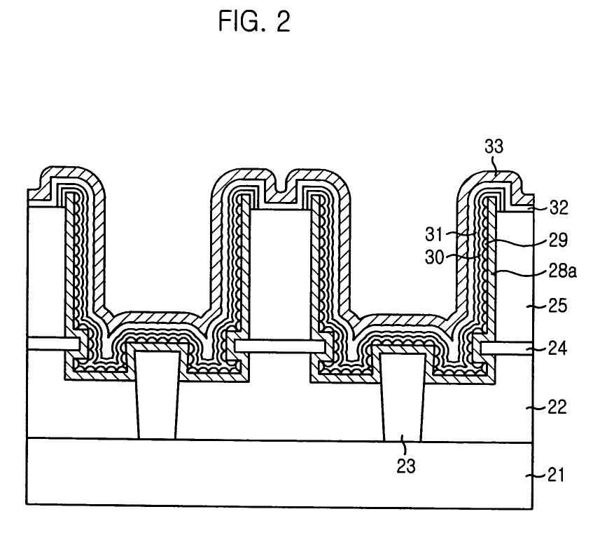

FIG. 2 is a cross-sectional view showing a capacitor structure in accordance with the present invention.

As shown, an interlayer insulating layer 22 is formed on a semiconductor substrate 21 and a storage node contact plug 23 is formed to be connected to the semiconductor substrate 21 by passing through the interlayer insulating layer 22. Thereafter, an etching barrier layer 24 and a storage node oxide layer 25 having an opening to expose the storage node contact plug 23 are formed on the interlayer insulating layer 22. The etching barrier layer 24 is projected like a chin, so that an undercut is provided below the etching barrier layer 24.

Subsequently, a bottom electrode 28A of a cylinder type, whose bottom portion is physically supported by the etching barrier layer 24, is formed on the resulting structure to be connected to the storage node contact plug 23. Namely, it has a shape that the bottom portion of the bottom electrode 28A is fitted to the undercut provided below the etching barrier layer 24. In order to increase a surface area of the bottom electrode, unevenness such a hemi-spherical grain 29 is formed on the bottom electrode 28A and a surface of the unevenness is nitrified to form a silicon nitride layer 30 acting as a first oxygen diffusion barrier layer.

Subsequently, an alumina layer 31 is formed on the silicon nitride layer 30 as a second oxygen diffusion barrier layer and a tantalum oxide layer 32 and a top electrode 33 are sequentially formed on the alumina layer 31.

As shown in FIG. 2, a dual oxygen diffusion barrier layer of the silicon nitride layer 30 and the alumina layer 31 is employed in order to prevent an oxygen diffusion toward the bottom electrode 28A during a thermal treatment process carried out after the tantalum oxide layer 32 is deposited as an dielectric layer of a capacitor in accordance with the present invention.

When the dual layer of the silicon nitride layer 30 and the alumina layer 31 is applied as the oxygen barrier layer, an oxygen diffusion can be efficiently prevented due to an excellent ability of the alumina layer 31 preventing an oxygen diffusion toward the bottom electrode 28A during the thermal treatment process after depositing the tantalum oxide layer 32 compared with that the silicon nitride is applied alone as the oxygen diffusion barrier layer. The excellent ability of the alumina layer 31 preventing the oxygen diffusion means that oxygen cannot diffuse through the alumina layer 31 because a bonding energy between aluminum and oxygen (Al—O) is very high.

As the hemi-spherical grains 29 are formed, a capacity of the capacitor can be increased. Furthermore, since the bottom electrode 28A is solidly supported by the undercut provided below the etching barrier layer 24, a bridge between bottom electrodes and lifting of the bottom electrode generated when the bottom electrode is collapsed can be prevented.

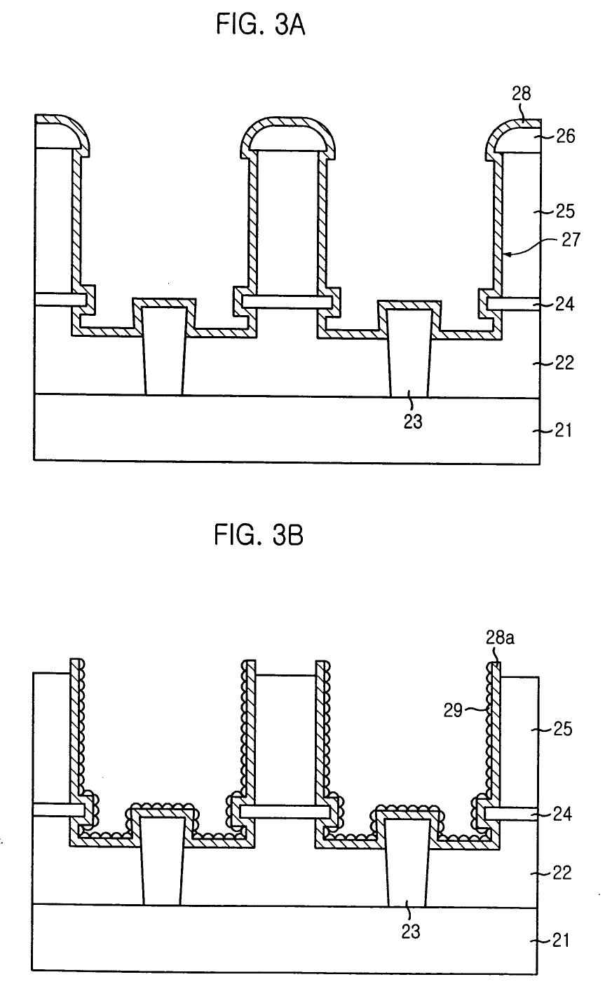

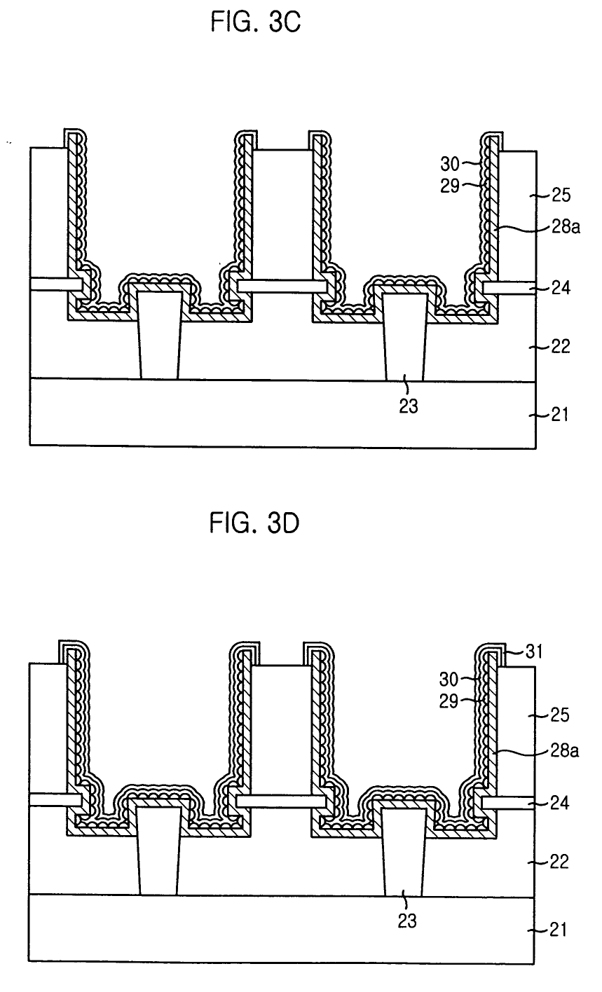

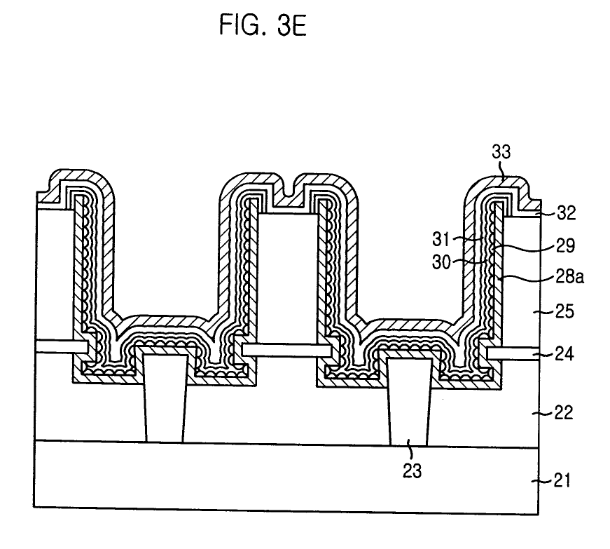

FIGS. 3A to 3E are cross-sectional views showing a method for fabricating the capacitor illustrated in FIG. 2 in accordance with the present invention.

Referring to FIG. 3A, an interlayer insulating layer 22 is formed on a semiconductor substrate 21 and then a contact hole is formed by etching the interlayer insulating layer 22 to expose a portion of the semiconductor substrate 21. A polysilicon layer as a conductive layer is deposited to fill the contact hole and a blanket etching process is carried out to thereby form a storage node contact plug 23. An etching barrier layer 24 and a storage node oxide layer 25 are sequentially deposited on the interlayer insulating layer 22 and the storage node contact plug 23. The storage node oxide layer 25 is formed with tetraethylorthosilicate (TEOS) and the etching barrier layer 24 is formed with silicon nitride. A polysilicon layer is employed as a hard mask 26. As well known, since it is difficult to etch the high thickness of storage node oxide layer 25 with only a photoresist, the hard mask 26 such a polysilicon layer is employed.

After the hard mask 26 is etched through mask and etching processes, the storage node oxide layer 25 is etched to the etching barrier layer by using the hard mask 26 as an etching mask. Subsequently, the etching barrier layer 24 is etched to thereby form a concave pattern which a bottom electrode will be formed. At this time, since the interlayer insulating layer below the etching barrier layer is heavily etched, a top surface and a portion of lateral side of the contact plug 23 are exposed.

Thereafter, a wet-etching process is additionally carried out to widen a width of the concave pattern 27 by etching the storage node oxide layer. The wet-etching process is carried out through a dip process using a wet chemical of a dilute HF, a chemical mixing a HF family or a chemical mixing an ammonia family. The reason that the wet-etching dip process is carried out is to widen a surface area of the bottom electrode and to physically solidly support the bottom portion of the bottom electrode.

Since the etching barrier layer 24 and the hard mask 26 having a different etching selectivity from the storage node oxide layer 25 are not etched during the wet-etching process, undercuts are generated below the hard mask 26 and the etching barrier layer 24, respectively. Namely, the hard mask 26 and the etching barrier layer 24 are projected like a chin. Next, an amorphous silicon layer 28 is deposited on the resulting structure.

Referring to FIG. 3B, a chemical mechanical polishing (CMP) process is carried out for the amorphous silicon layer 28 until a surface of the storage node oxide layer 25 is exposed, so that the bottom electrode 28A crystallizing the amorphous silicon layer 28 is isolated from the neighboring bottom electrode. At this time, the hard mask 26 is also removed during the CMP process.

Subsequently, a wet etching process is carried out to make that a top side of the storage node oxide layer 25 is positioned below that of the bottom electrode 28A to prevent that the neighboring bottom electrodes are connected each other when hemi-spherical grains (HSGs) are formed. The HSGs are grown to increase a surface area of the bottom electrode 28A.

Referring to FIG. 3C, a silicon nitride layer 30 is formed on the bottom electrode 28A through a nitrification process of a surface of the bottom electrode 28A. The nitrification process can be carried out by using a plasma nitrification process performed with a plasma treatment or a rapid thermal nitrification (RTN) process performed at a high temperature using a NH₃ gas. The RTN process is carried out at a temperature of about 500° C. to about 850° C., at an NH₃ gas flow rate of about 1 slm (standard litter per minute) to about 20 slm and for about 60 seconds to about 180 seconds in an atmospheric pressure. The plasma nitrification process is carried out at an NH₃ gas flow rate of about 10 sccm to about 1000 sccm, at a RF power of about 50 W to about 400 W for generating a plasma, at a pressure of about 0.1 torr to 2 torr and for about 30 to about 300 seconds.

Referring to FIG. 3D, an alumina (Al₂O₃) layer 31 is formed with a thickness of about 10 to about 30 on the silicon nitride layer 30. The alumina layer 31 is used as a passivation layer on a surface of the bottom electrode 28A. The alumina layer is deposited by using an ALD method or an MOCVD method.

Hereinafter, the ALD method for forming the alumina layer 31 will be described. After the semiconductor substrate 21, in which the bottom electrode 28A is formed, is loaded into a deposition chamber, TMA source gas is inserted into the deposition chamber with a substrate temperature of about 350 to about 500 to thereby absorb the TAM source gas onto the surface of the silicon nitride layer 30. Thereafter, in order to purge non-reacted TMA source gas and by-products, an N₂ gas or an Ar gas flows into the chamber, or a vacuum pump is used to remove remaining gas. Subsequently, a reaction gas, a H₂O gas or an O₃ gas is introduced into the chamber to thereby induce a surface reaction with the adsorbed TMA source, so that an alumina layer 31 is deposited. In order to remove the non-reacted reaction gas and by-products, a N₂ gas or an Ar gas flows to the chamber, or a vacuum pump is used. As mentioned above, as the steps providing the TMA source, introducing the reaction gas and purging the chamber is repeatedly carried out, the alumina layer 31 having good step coverage is deposited with a thickness of about 10 to 30.

When the alumina layer 31 is deposited by using the MOCVD method, an Al(OC₂H₅)₃ source and an O₂ gas are provided into a deposition chamber at a temperature of about 350° C. to about 500° C. At this time, if the deposition process is carried out at a temperature of below 300° C., since a carbon impurity contained in an alumina source remains, the remaining impurity makes an impurity concentration of the dielectric layer increased, so that a current leakage cannot be prevented. Also, if the deposition process is carried out at a temperature of above 500° C., an oxidation of the bottom electrode 28A is accompanied.

Referring to FIG. 3E, the tantalum oxide layer 32 is deposited by using a metal organic chemical vapor deposition (MOCVD) method or an ALD method. When the tantalum oxide layer 32 is deposited by using the MOCVD method, a tantalum ethylate (Ta(OC₂H₅)₅) flows into a deposition chamber by using an N₂ gas as a carrier gas at a gas flow rate of about 350 sccm to about 450 sccm. After an oxygen gas as a reaction gas (or an oxidizing agent) flows at a gas flow rate of about 10 sccm to about 1000 sccm, the tantalum oxide layer 32 is deposited by thermally decomposing the tantalum ethylate provided onto the semiconductor substrate heated at a temperature of about 150° C. to about 200° C. At this time, the reaction chamber is maintained at a pressure of about 0.2 torr to about 10 torr. The tantalum ethylate, which is usually used as a source for forming the tantalum oxide layer 32, is a liquid state at a room temperature and is vaporized at a temperature of about 145° C. In order to easily react the tantalum ethylate, it is preferred to vaporize the tantalum ethylate. Therefore, after the tantalum ethylate is vaporized at a vaporizer maintained at a temperature of about 170° C. to 190° C., the vaporized tantalum ethylate is provided to the reaction chamber by using an N₂ gas as a carrier gas.

Thereafter, a thermal treatment process is carried out by crystallizing the tantalum oxide layer 32 and reducing impurities and oxygen depletion. The tantalum oxide layer 21 is crystallized and impurities such carbon contained in the tantalum oxide layer 21 are removed. Also, in order to compensate the oxygen depletion, the thermal treatment process is carried out at an ambient of an N₂O gas or an O₂ gas and a temperature of about 600° C. to 750° C. Since the alumina layer 31 is crystallized at the same time during the thermal treatment process of high temperature, an additional thermal treatment process may be not needed to crystallize the alumina layer 31. Specially, since the alumina layer 31 is deposited at a temperature of about 350° C. to about 500° C., impurities do not exist in the alumina layer 31, so that a thermal treatment process of low temperature may not needed to remove the impurities.

A top electrode 33 is formed oh the tantalum oxide layer 32. A titanium nitride (TiN) layer or a stacked layer of a titanium nitride layer and a polysilicon layer (polysilicon/TiN) is formed on a thermally treated tantalum oxide layer 32, so that an MIS capacitor is completed.

As mentioned above, as the dual layer as the oxygen diffusion barrier layer of the nitride layer 30 and the alumina layer 31 is formed between the bottom electrode 28A and the tantalum oxide layer 32, oxygen diffused to the bottom electrode 28A during the post thermal treatment process can be suppressed, so that formation of a low-k dielectric layer between the bottom electrode 28A and the tantalum oxide layer 32 can be prevented.

Since a bonding energy of the alumina with oxygen (Al—O) is higher than that of the tantalum oxide, oxidation of the bottom electrode 28A can be suppressed. Also, a molecule structure of the alumina is solider and has less impurities than that of the tantalum oxide, so that a diffusion of oxygen contained in an oxidizing agent (O₂, N₂O) can be effectively prevented.

Also, as the alumina layer is used, an increased breakdown voltage and a low leakage current level can be obtained.

While the present invention has been described with respect to the particular embodiments, it will be apparent to those skilled in the art that various changes and modifications may be made without departing from the spirit and scope of the invention as defined in the following claims.

What is claimed is:

1. A capacitor comprising:
an electrode;
an oxygen diffusion barrier layer containing aluminum on the electrode;
a dielectric layer on the oxygen diffusion barrier layer; and
a top electrode on the dielectric layer.

2. The capacitor as recited in claim 1, further comprising an oxygen diffusing layer containing nitrogen between the bottom electrode and the oxygen diffusion layer containing aluminum.

3. The capacitor as recited in claim 1, wherein the bottom electrode includes hemi-spherical grains on a surface thereof.

4. The capacitor as recited in claim 1, wherein the oxygen diffusion barrier layer is an alumina layer.

5. A method fabricating a capacitor, comprising the steps of:
a) forming an bottom electrode;
b) forming an oxygen diffusion barrier layer containing aluminum on the bottom electrode;
c) forming a dielectric layer on the oxygen diffusion barrier layer; and
d) forming a top electrode on the dielectric layer.

6. The method as recited in claim 5, wherein the step a) includes the steps of:
a1) forming a hemi-spherical grains on a surface of the bottom electrode; and
a2) forming an oxygen diffusion layer containing nitrogen on the bottom electrode.

7. The method as recited in claim 6, wherein the oxygen diffusion barrier layer containing nitrogen is formed by using a rapid thermal process or a plasma nitride process.

8. The method as recited in claim 5, wherein the oxygen diffusion barrier is an alumina layer.

9. The method as recited in claim 8, wherein the alumina layer is formed by using a low pressure chemical vapor deposition technique or an atomic layer deposition technique.

10. The method as recited in claim 8, wherein the alumina layer is formed at a temperature of about 350° C. to 500° C.
